(19) United States
(12) Patent Application Publication
(10) Pub. No.: US 2012/0204931 A1
(43) Pub. Date: Aug. 16, 2012

(54) METHOD FOR MANUFACTURING ORGANIC THIN FILM SOLAR CELL MODULE

(76) Inventor: Takahiro Seike, Ibaraki (JP)

(21) Appl. No.: 13/503,046

(22) PCT Filed: Oct. 26, 2010
(86) PCT No.: PCT/JP2010/068961

§ 371 Date: Apr. 20, 2012

(30) Foreign Application Priority Data
Oct. 29, 2009 (JP) 2009-249516

(51) Int. Cl. H01L 31/042; B26D 3/06; H01L 51/48

(52) U.S. Cl. 136/244; 438/68; 83/875; 257/E51.012

(57) ABSTRACT

Provided is an organic thin film solar cell module that does not impair functions and in which layers are isolated. A method is for manufacturing an organic thin film solar cell module (100) in which a plurality of organic photovoltaic cells are arranged on a substrate, each of which comprises a layered structure comprising a pair of electrodes of a first electrode (22) and a second electrode (24) and one layer of an organic thin film or one or more layers of organic thin films placed between the pair of electrodes. The method comprises the steps of: cutting a layered structure (50A) including one layer of the organic thin film or one or more layers of the organic thin films using a blade structure without heating, thereby forming a groove that passes through the layered structure including one layer of the organic thin film.

### TECHNICAL FIELD

The present invention relates to a method for manufacturing an organic thin film solar cell module in which a plurality of organic photovoltaic cells are integrated on the same substrate, and a device for manufacturing preferably used for the method for manufacturing.

### BACKGROUND ART

An organic thin film solar cell module is usually manufactured by a method for manufacturing comprising the steps of: (1) preparing a substrate; (2) forming a first electrode on the substrate; (3) forming a first charge transport layer on the first electrode; (4) forming an active layer on the first charge transport layer; (5) forming a second charge transport layer on the active layer; and (6) forming a second electrode on the second charge transport layer.

In other words, the organic thin film solar cell module is manufactured by sequentially film forming a plurality of functional layers such as a charge transport layer and an active layer. Each functional layer is patterned in a desired shape by any preferable patterning step depending on materials and the like for each functional layer when every each corresponding firm forming step is completed.

For example, at the time of manufacturing a dye sensitizing type solar cell, a patterning step in which a conductive layer is segmentalized on the substrate by burning off the conductive layer with a soldering iron or a heated stylus-type blade structure such as a heated razor blade is known (Patent Document 1). In addition, at the time of manufacturing an inorganic thin film solar cell comprising a chalcopyrite type light absorbing layer, a patterning step in which isolation is performed by combining different means such as heating elimination with laser irradiation and mechanical cutting using a metal stylus is known (refer to Patent Document 2).

### RELATED ART DOCUMENTS

### Patent Document

Patent Document 1: U.S. 20040031520 A
Patent Document 2: JP 2007-317885 A

### DISCLOSURE OF INVENTION

However, if the foregoing conventional patterning step using heat is applied for the method for manufacturing an organic thin film solar cell module, organic compounds comprising in the functional layer such as the active layer may be deactivated or decomposed by the heat, or lower constitution than a layer for patterning such as the substrate may be damaged. An organic thin film comprising organic compounds comprised in the organic thin film solar cell module is significantly soft compared with, for example, an inorganic film and adhesion to a layer directly beneath the organic thin film is low. Consequently, in a patterning step by conventional mechanical cutting, breakdown of the layer structure such as peeling of the layer may occur. As a result, the organic photovoltaic cell may malfunction. Also, the organic photovoltaic cell may malfunction by a large amount of dust generated by the cutting. In order to remove dust (dust removal), a dust removal apparatus is further required.

The inventors of the present invention have eagerly investigated an organic thin film solar cell module and a method for manufacturing thereof and have accomplished the present invention.

Namely, the present invention provides the following method for manufacturing the organic thin film solar cell module and a device for manufacturing thereof.

[1] A method for manufacturing an organic thin film solar cell module in which a plurality of organic photovoltaic cells are arranged on a substrate, each of which comprises a layered structure comprising a pair of electrodes of a first electrode and a second electrode and one layer of an organic thin film or one or more layers of organic thin films placed between the pair of electrodes, the method comprising the steps of:

cutting the layered structure including one layer of the organic thin film or one or more layers of the organic thin films using a blade structure without heating, thereby forming a groove that passes through the layered structure comprising one layer of the organic thin film or one or more layers of the organic thin films to exposes a surface of a layer provided directly beneath the layered structure.

[2] A method for manufacturing an organic thin film solar cell module, the method comprising the steps of:

forming a plurality of first electrodes on a main surface of a substrate;

forming a first charge transport layer on the first electrode formed on the substrate;

first cutting to form a first groove in a region between the first electrodes for exposing the main surface of the substrate by passing through the first charge transport layer;

forming an active layer covering over the first charge transport layer, and a second charge transport layer covering over the active layer;

second cutting to form a second groove for exposing a part of the first electrode by passing through the first charge transport layer, the active layer, and the second charge transport layer;

forming a second electrode covering over the second charge transport layer and embedded in the second groove; and

third cutting to form a third groove for exposing a part of the first electrode by passing through the second electrode, the second charge transport layer, the active layer, and the first charge transport layer, threreby isolating a plurality of organic photovoltaic cells,

wherein at least one of the first cutting, the second cutting, and the third cutting comprises cutting using a blade structure without heating.

[3] The method for manufacturing an organic thin film solar cell module according to above [1] or [2], wherein the step of cutting comprises cutting by a push cutting process using a disk-shaped blade structure.
[4] The method for manufacturing an organic thin film solar cell module according to above [1] or [2], wherein the step of cutting comprises cutting by a pull cutting process using a stylus-shaped blade structure. [5] The method for manufacturing an organic thin film solar cell module according to above [1] or [2], wherein the step of cutting comprises cutting by a pull cutting process using a flat blade-shaped blade structure.
[6] The method for manufacturing an organic thin film solar cell module according to above [4] or[5], wherein the step of cutting comprises cutting by setting an angle formed by the blade structure and the organic thin film being a cutting target at 30° to 60°.
[7] The method for manufacturing an organic thin film solar cell module according to any one of above [1] to [6], wherein a material of the blade structure is selected from the group consisting of a metal, an alloy, a ceramic, and a resin.
[8] The method for manufacturing an organic thin film solar cell module according to any one of above [1] to [7], wherein the radius of curvature at a tip of the blade structure is 5 μm to 1000 μm.
[9] An organic thin film solar cell module produced by the method for manufacturing according to any one of above [1] to [8].
[10] An apparatus for manufacturing an organic thin film solar cell module, the apparatus comprising:

a carrier roll that supports and carries a substrate on which an organic thin film is provided; and

a blade structure that cuts the organic thin film on the substrate supported by the carrier roll in contact with the organic thin film in a state without heating.

[11] The apparatus for manufacturing an organic thin film solar cell module according to above [10], wherein the blade structure has a disk shape capable of performing a push cutting process.
[12] The apparatus for manufacturing an organic thin film solar cell module according to above [10], wherein the blade structure has a stylus shape.
[13] The apparatus for manufacturing an organic thin film solar cell module according to above [10], wherein the blade structure has a flat blade shape.

### BRIEF DESCRIPTION OF DRAWINGS

FIG. 1 is a schematic cross-sectional view illustrating constitution of an organic thin film solar cell module manufactured by a method for manufacturing according to the present invention.

FIG. 2-1 is a schematic side view illustrating an apparatus for manufacturing according to a first embodiment.

FIG. 2-2 is a schematic front view illustrating the apparatus for manufacturing according to the first embodiment.

FIG. 3-1 is a schematic side view illustrating an apparatus for manufacturing according to a second embodiment.

FIG. 3-2 is a schematic front view illustrating the apparatus for manufacturing according to the second embodiment.

FIG. 4-1 a schematic side view illustrating an apparatus for manufacturing according to a third embodiment.

FIG. 4-2 is a schematic front view illustrating the apparatus for manufacturing according to the third embodiment.

FIG. 5-1 is a photograph (1) shown an optical microscope image of the cut region.

FIG. 5-2 is a photograph (2) shown an optical microscope image of the cut region.

FIG. 5-3 is a photograph (3) shown an optical microscope image of the cut region.

### EXPLANATIONS OF LETTERS OR NUMERALS

10 Substrate
10A Electrode Forming Region
10B Electrode Non-forming Region
22 First Electrode
24 Second Electrode
24a Contact
32 First Charge Transport Layer
34 Second Charge Transport Layer
40 Active Layer
50 Layered Structure
50A First Layered Body
50B Second Layered Body
60 Carrier Roll
70 Blade Structure
70a Apical Part
70b Stylus Axis Part
80 Scribing Region (Cut Region)
100 Organic Thin Film Solar Cell Module
100A1 First Cell (Forming Region)
100A2 Second Cell
100B Part between Cells (Region)
C Central Rotation Axis
C1 First Central Rotation Axis
C2 Second Central Rotation Axis
X First Groove Part
Y Second Groove Part
Z Third Groove Part

### DESCRIPTION OF EMBODIMENTS

### Organic Thin Film Solar Cell Module

An organic thin film solar cell module according to the present invention may basically form the same module structure as an existing solar cell module. The organic thin film solar cell module generally forms a structure in which a plurality of organic photovoltaic cells (cells) are configured on a substrate (a supporting substrate) made of a metal, a ceramic or the like, and a filling resin, protection glass or the like cover the organic photovoltaic cells to take light from a opposite side of the substrate. However, a structure in which a transparent material such as reinforced glass is used for the substrate and light is taken from a side of the transparent substrate by configuring the organic photovoltaic cells on the transparent substrate may be formed.

As structure examples of the module structure, module structures referred to as a superstraight type, a substrate type or a potting type; a substrate-integrated module structure used for an amorphous silicon solar cell and the like; and other structures are specifically known.

The organic thin film solar cell module according to the present invention may be selected from these module structures depending on intended use, and place and environment of use.

A representative superstraight type or substrate type module structure forms a structure in which the organic photovoltaic cells are arranged at constant intervals between the substrates whose one side or both sides are transparent and to which antireflection treatment is applied; the adjacent organic photovoltaic cells are connected with each other by a contact electrode (an embedded electrode), a metal lead, a flexible wiring or the like; a collecting electrode is arranged in an outer edge part; and generated electric power is taken out to out of the module.

In order to protect the organic photovoltaic cell and to improve power collection efficiency, various kinds of plastic materials such as ethylene-vinyl acetate (EVA) may be used depending on purposes in the form of a film or a filling resin between the substrate and the organic photovoltaic cells. When the module is used in places where its surface is not required to be covered with a hard material, such as a place where impact from the outside seldom occurs, one side of the substrate may be eliminated by adding a protection function in a manner that a surface protection layer is constituted by a transparent plastic film and the filling resin is cured. In order to secure inner sealing and rigidity of the module, circumference of the substrate is sandwiched to fix by a frame made by a metal and clearance between the substrate and the frame is tightly sealed by a sealing material. The organic photovoltaic cell can be constituted on a curved surface by using the organic photovoltaic cell itself, a flexible material for the substrate, the filling material and the sealing material.

In the case of a solar cell module using a flexible support such as a polymer film, the solar cell module can be manufactured by sequentially forming the photovoltaic cells on the roll-shape support with pulling out the support and cutting the support in a desired size, and then sealing the circumference part by a material having flexibility and a moisture-proof property.

A module structure referred to as “SCAF” described in Solar Energy Materials and Solar Cells, 48, p 383-391 can also be used. The solar cell module using a flexible support can be used by fixing the module on a curved glass and the like with an adhesive.

Hereinafter, the present invention is described in detail with reference to the drawings. In the organic thin film solar cell module having the foregoing constitution, descriptions of exterior parts such as a frame and a protection member are omitted because these are not essential component of the present invention, and the organic photovoltaic cell and the method for manufacturing thereof are centrally described.

In the following description, each drawing only schematically illustrates shapes, sizes and locations of constituent elements in such a degree that the present invention can be understood. Therefore, the present invention is not particularly limited by this description. In addition, the same references may be assigned and illustrated to the same constituent and redundant description thereof may be omitted.

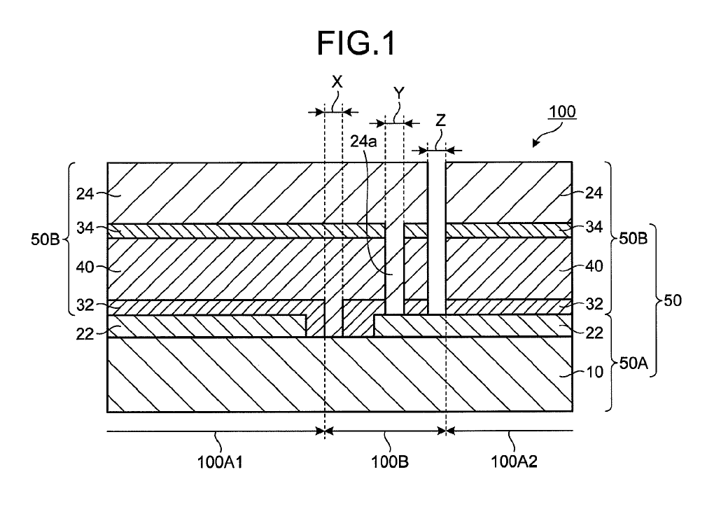

First, constitution of an organic thin film solar cell module that can be manufactured by a method for manufacturing according to the present invention, and the method for manufacturing thereof is described with reference to FIG. 1.

FIG. 1 is a schematic cross-sectional view illustrating the constitution of the organic thin film solar cell module manufactured by the method for manufacturing according to the present invention.

As shown in FIG. 1, an organic thin film solar cell module 100 comprises a pair of electrodes of a first electrode 22 and a second electrode 24, an active layer 40 placed between the pair of electrodes, and comprises a plurality of organic photovoltaic cells (comprising first cells 100A1 and second cells 100A2) arranged on a substrate 10.

Among the pair of electrodes, at least one electrode into which light is incident, that is, at least one of the electrodes is a transparent or semitransparent electrode that can transmit incident light (sunlight) having a wavelength required for power generation.

The organic photovoltaic cell comprises the pair of electrodes of the first electrode 22 being, for example, an anode and the second electrode 24 being, for example, a cathode, and the active layer 40 placed between the pair of electrodes. The polarity of the first electrode 22 and the second electrode 24 may be any preferable polarity corresponding to a cell structure. It is also possible that the first electrode 22 be a cathode and the second electrode 24 be an anode.

The transparent or semitransparent electrodes may be a conductive metal oxide film or a semitransparent thin metal film. Specifically, films made of conductive materials such as indium oxide, zinc oxide, tin oxide, and indium-tin oxide (may be referred to as ITO) and indium-zinc oxide that are complex materials thereof; NESA; gold, platinum, silver, copper, and the like are used as the electrodes. Films of ITO, indium-zinc oxide, and tin oxide are preferable. Examples of methods for preparing the electrode may include a vacuum evaporation method, a sputtering method, an ion plating method, and a plating method. As the electrode, an organic transparent conductive film such as polyaniline and a derivative thereof and polythiophene and a derivative thereof may be used.

As electrode materials for an opaque electrode, a metal, a conductive macromolecule, and the like can be used. Specific examples of the electrode material for the opaque electrode may include metals such as lithium, sodium, potassium, rubidium, cesium, magnesium, calcium, strontium, barium, aluminum, scandium, vanadium, zinc, yttrium, indium, cerium, samarium, europium, terbium and ytterbium; and alloys made of two or more of these metals, or alloys made of one or more metals and one or more metals selected from the group consisting of gold, silver, platinum, copper, manganese, titanium, cobalt, nickel, tungsten and tin; graphite, intercalation graphite, polyaniline and a derivative thereof, and polythiophene and a derivative thereof. Examples of the alloys may include a magnesium-silver alloy, a magnesium-indium alloy, a magnesium-aluminum alloy, an indium-silver alloy, a lithium-aluminum alloy, a lithium-magnesium alloy, a lithium-indium ally, and a calcium-aluminum alloy.

The organic photovoltaic cell is usually formed on the substrate. In other words, the first cell 100A1 and the second cell 100A2 are provided on the main surface of the substrate 10.

A material for the substrate 10 may be any material that is not chemically changed when the electrode is formed and an organic thin film comprising organic compounds is formed. Examples of the material for the substrate 10 may include a glass, a plastic, a polymer film, and silicon.

When the substrate 10 is opaque, that is, the substrate does not transmit incident light, the second electrode 24 that faces the first electrode 22 and is provided on the opposite side of the substrate (in other words, the electrode that is further from the substrate 10) is preferably a transparent electrode or a semitransparent electrode that can transmit necessary incident light.

The active layer 40 is sandwiched between the first electrode 22 and the second electrode 24. The active layer 40 comprises an electron acceptor compound (an n-type semiconductor) and an electron donor compound (a p-type semiconductor) in a mixed manner. In this example, the active layer is a bulk hetero type organic thin film. The active layer 40 has an essential function for photovoltaic function that can generate charges (holes and electrons) using incident light energy.

As described above, the active layer comprised in the organic photovoltaic cell comprises the electron donor compound and the electron acceptor compound.

The electron donor compound and the electron acceptor compound are relatively determined by energy level of these compounds. Therefore, one compound can become either the electron donor compound or the electron acceptor compound.

Examples of the electron donor compounds may include pyrazoline derivatives, arylamine derivatives, stilbene derivatives, triphenyldiamine derivatives, oligothiophene and derivatives thereof, polyvinylcarbazole and derivatives thereof, polysilane and derivatives thereof, polysiloxane derivatives having aromatic amines in the main chain or side chains thereof, polyaniline and derivatives thereof, polythiophene and derivatives thereof, polypyrrole and derivatives thereof, polyphenylene vinylene and derivatives thereof, and polythienylene vinylene and derivatives thereof.

Examples of the electron acceptor compounds include oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof, polyfluorene and derivatives thereof, fullerenes such as C₆₀ fullerene and derivatives thereof, phenanthrene derivatives such as bathocuproine, metal oxides such as titanium oxide, and carbon nanotubes. As the electron acceptor compounds, titanium oxide, carbon nanotubes, fullerenes, and fullerene derivatives are preferable, and fullerenes and fullerene derivatives are particularly preferable.

Examples of the fullerenes may include C₆₀ fullerene, C₇₀ fullerene, C₇₆ fullerene, C₇₈ fullerene, and C₈₄ fullerene.

Examples of the fullerene derivatives may include derivatives of each C₆₀ fullerene, C₇₀ fullerene, C₇₆ fullerene, C₇₈ fullerene, and C₈₄ fullerene. Examples of specific structures of the fullerene derivatives may include the following structures.

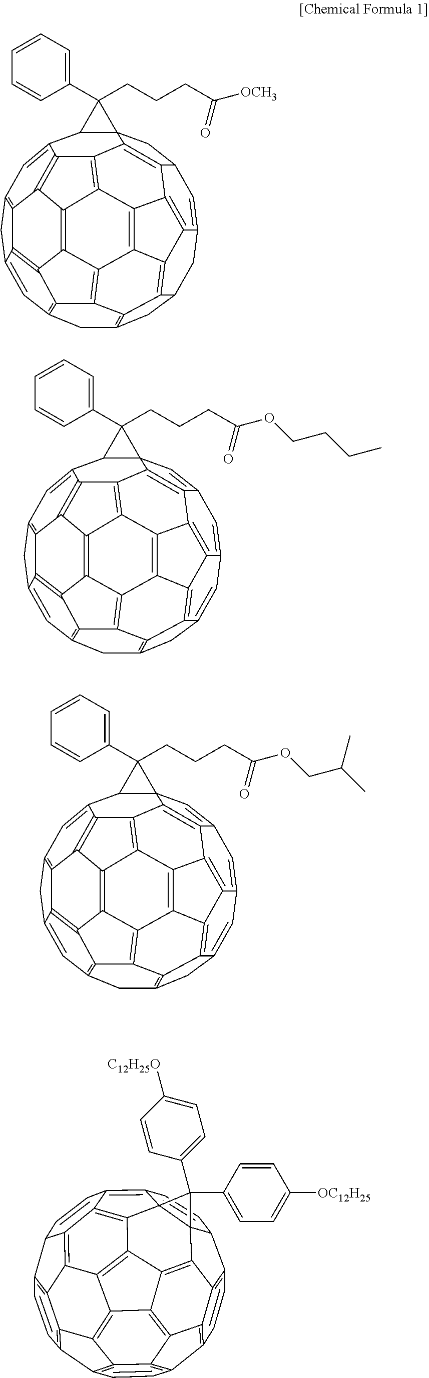

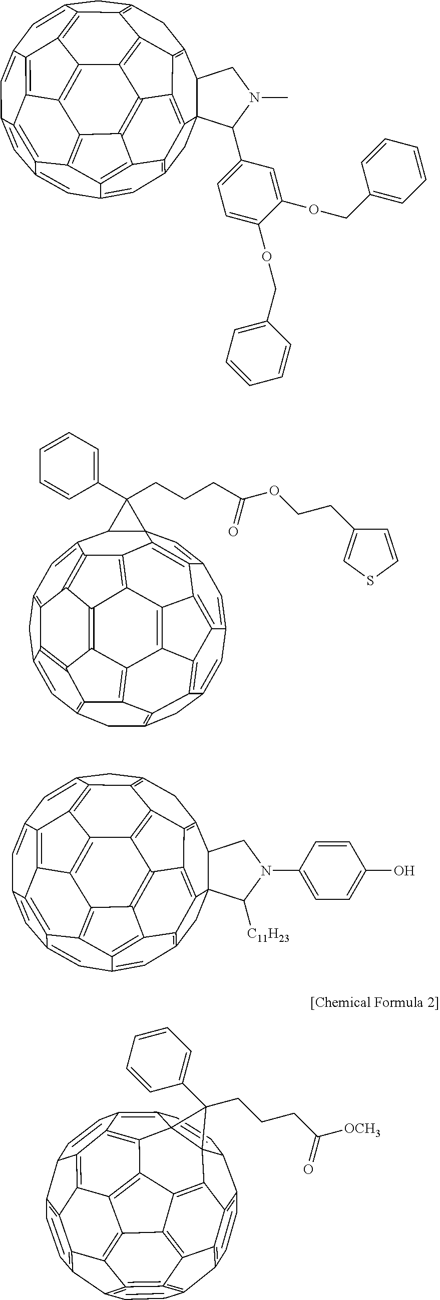

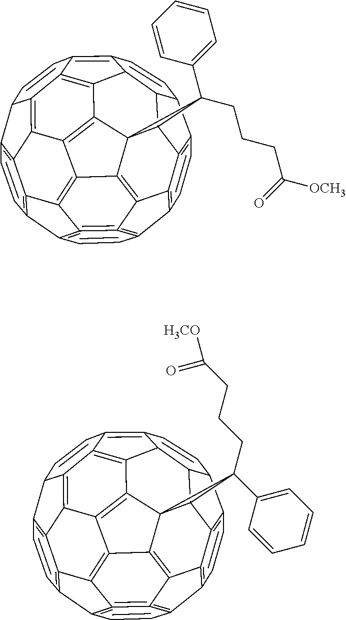

In addition, examples of fullerene derivatives may include [6,6]-Phenyl C₆₁ butyric acid methyl ester (C₆₀PCBM), [6,6]-Phenyl C₇₁ butyric acid methyl ester (C₇₀PCMB), [6,6]-Phenyl C₈₅ butyric acid methyl ester (C₈₄PCBM), and [6,6]-Thienyl C₆₁ butyric acid methyl ester.

When the fullerene derivatives are used as the electron acceptor compounds, an amount of the fullerene derivative is preferably 10 parts by weight to 1000 parts by weight, and more preferably 20 parts by weight to 500 parts by weight per 100 parts by weight of the electron donor compound.

An amount of the electron acceptor compound in the bulk hetero type active layer comprising the electron acceptor compound and the electron donor compound is preferably 10 parts by weight to 1000 parts by weight, and more preferably 50 parts by weight to 500 parts by weight per 100 parts by weight of the electron donor compound.

Usually, the thickness of the active layer is preferably 1 nm to 100 μm, more preferably 2 nm to 1000 nm, further preferably 5 nm to 500 nm, and particularly preferably 20 nm to 200 nm.

Here, an operation mechanism of the organic photovoltaic cell is simply described. Energy of incident light that transmits though the transparent or semitransparent electrode and is incident into the active layer is absorbed by the electron acceptor compound and/or the electron donor compound, whereby exciters in which electrons and holes are combined are generated. When the generated exciters are moved and reached to a hetero-junction interface where the electron acceptor compound and the electron donor compound are joined, difference of each of HOMO energy and LUMO energy at the interface causes separation of electrons and holes and generates charges (electrons and holes) that can move independently. The organic photovoltaic cell can take out electric energy (electric current) to out of the cell by moving the generated charges to the electrodes (the cathode and the anode).

In the organic photovoltaic cell, an additional intermediate layer other than the active layer 40 can be provided as a means for improving photovoltaic efficiency between at least one electrode of the first electrode 22 and the second electrode 24, and the active layer. As materials for the additional intermediate layer, a halide of an alkali metal and an alkaline-earth metal such as lithium fluoride and an oxide of an alkali metal and an alkaline-earth metal can be used. In addition, the materials may be fine particles of inorganic semiconductor such as titanium oxide or PEDOT (poly-3,4-ethylenedioxythiophene).

Examples of the additional layer may include the charge transport layer that transports holes or electrons (a hole transport layer, an electron transport layer).

Any preferable material can be used for a material constituting the charge transport layer. When the charge transport layer is the electron transport layer, examples of the material may include 2,9-dimethyl-4,7-diphenyl-1,10-phenanthroline (BCP). When the charge transport layer is the hole transport layer, examples of the material may include PEDOT.

The intermediate layer that may be provided between the first electrode 22 and the second electrode 24, and the active layer 40 may be a buffer layer. Materials used for the buffer layer may be a halide of an alkali metal or an alkaline-earth metal such as lithium fluoride and oxides such as titanium oxide. When an inorganic semiconductor is used, the inorganic semiconductor can be used in the form of fine particles.

The constitution of the organic photovoltaic cell is described more specifically. The first electrode 22 is provided on the main surface of the substrate 10. A layered structure of the substrate 10 and the first electrode 22 is referred to as a first layered body 50A.

A first charge transport layer 32 is provided on the first electrode 22. The first charge transport layer 32 is the hole transport layer when the first electrode 22 is an anode and is the electron transport layer when the first electrode 22 is a cathode.

The active layer 40 is provided on the first charge transport layer 32. A second charge transport layer 34 is provided on the active layer 40. The second charge transport layer 34 is the electron transport layer when the first electrode 22 is an anode and is the hole transport layer when the first electrode 22 is a cathode. The second electrode 24 is provided on the second charge transport layer 34. A layered structure of those first charge transport layer 32, active layer 40, the second charge transport layer 34, and the second electrode 24 is referred to as a second layered body 50B.

In this embodiment, the single layer active layer in which the active layer 40 is the bulk hetero type that is made by mixing the electron acceptor compound and the electron donor compound is described. However, the active layer 40 may be constituted by a plurality of layers. For example, the active layer may be a hetero-junction type in which an electron acceptor layer comprising the electron acceptor compound such as the fullerene derivative and an electron donor layer comprising the electron donor compound such as P3HT are joined.

Here, one example of layer constitution in which the organic photovoltaic cell can be formed.
a) Anode/Active layer/Cathode
b) Anode/Hole transport layer/Active layer/Cathode
c) Anode/Active layer/Electron transport layer/Cathode
d) Anode/Hole transport layer/Active layer/Electron transport layer/Cathode
e) Anode/Electron donor layer/Electron acceptor layer/Cathode
f) Anode/Hole transport layer/Electron donor layer/Electron acceptor layer/Cathode
g) Anode/Electron donor layer/Electron acceptor layer/Electron transport layer/Cathode
h) Anode/Hole transport layer/Electron donor layer/Electron acceptor layer/Electron transport layer/Cathode
   (Here, the symbol “/” represents that layers sandwiching the symbol “/” are adjacently stacked each other).

The layer constitution may be either a form in which the anode is provided at the nearer side to the substrate or a form in which the cathode is provided at the nearer side to the substrate.

Each of the layers may be constituted by not only a single layer but also a layered body made of two or more layers.

The first cell 100A1 and the second cell 100A2 are isolated by the part between cells 100B that is not functioned as the organic photovoltaic cell. The second electrode 24 of the first cell 100A1 and the second cell 100A2 are electrically connected by a contact (electrode) 24a.

### Method for Manufacturing

Subsequently, a method for manufacturing the organic thin film solar cell module comprising the foregoing constitution.

In a method for manufacturing an organic thin film solar cell module according to the present invention, the method for manufacturing an organic thin film solar cell module in which a plurality of organic photovoltaic cells comprising a layered structure comprising a pair of electrodes of a first electrode and a second electrode and one layer of an organic thin film or one or more layers of organic thin films placed between the pair of electrodes are arranged on a substrate, the method comprises the steps of: cutting a layered structure comprising one layer of the organic thin film or one or more layers of the organic thin films using a blade structure without heating, thereby forming a groove that passes through the layered structure comprising one layer of the organic thin film or one or more layers of the organic thin films and exposes a surface of a layer provided directly beneath the layered structure.

First, the substrate 10 is prepared for manufacturing the organic thin film solar cell module. The substrate 10 is a planar substrate having two facing surfaces of main surfaces. For preparing the substrate 10, a substrate in which a conductive material thin film being possible to be a material for an electrode such as indium tin oxide is previously provided on one main surface of the substrate 10 may be prepared.

When the conductive material thin film is not provided on the substrate 10, the conductive material thin film is formed on one main surface of the substrate 10 by any preferable method. Subsequently, the conductive material thin film is patterned. The conductive material thin film is patterned by any preferable method such as a photolithography process and an etching process, thereby forming a first electrode 22 that is formed by a plurality of patterns electrically isolated each other. In this step, a part of the main surface of the substrate 10 is exposed in the region where the first electrode 22 is not formed.

Subsequently, the first charge transport layer 32 is formed in accordance with a common procedure on the entire surface of the substrate 10 on which the first electrode 22 is formed.

Subsequently, a first groove X for exposing the surface of the substrate 10 is processed and formed by passing from the surface of the first charge transport layer 32 through the first charge transport layer 32 using a blade structure according to the present invention in the part between the cells 100B and in a region between a plurality of first electrodes (patterns) 22 (detailed blade structure is described below). By forming this first groove X, the first electrode 22 of the first cells 100A1 and the first electrode 22 of the second cells 100A2 are electrically isolated by separating them using the first groove X (first cutting step).

Subsequently, the active layer 40 covering over the first charge transport layer 32 is formed. The active layer 40 can be formed by a coating method such as a spin coating method in which a coating liquid is applied.

Subsequently, the second charge transport layer 34 covering over the active layer 40 is formed. Subsequently, a second groove Y in the part between the cells 100B is processed and formed by passing from the surface of the second charge transport layer 34 through the second charge transport layer 34, the active layer 40, and the first charge transport layer 32 to the surface of the first electrode 22 of the second cell 100A2, that is, the surface of the first layered body 50A using the blade structure according to the present invention (second cutting step). This second groove Y is used as a contact groove (or a contact hole) for electrically connecting the second electrode 24 of the first cell 100A1 and the first electrode of the second cell 100A2. Consequently, the second groove Y may strictly not be constitution in which the active layer 40 and the first charge transport layer 32 are divided in two parts on the first electrode 22.

Subsequently, a contact (an electrode) 24a that covers over the second charge transport layer 34 and is in contact with the first electrode 22 by being embedded in the second groove Y is formed. The contact 24a electrically connects between the second electrode 24 of the first cell 100A1 and the first electrode 22 of the second cell 100A2.

The second electrode 24 may be formed by the foregoing coating method, or formed by any conventionally known preferable method such as an evaporation method.

As described above, the second groove Y is a structure for the contact that electrically connects between the first electrode 22 and the second electrode 24. A shape of the second groove Y may be formed as a groove-shape or a column-shape such as a cylindrical shape. Although the shape is not particularly limited, an example in which the shape is formed as a groove-shape is described.

The adjacent organic photovoltaic cells are electrically connected with each other by forming the contact 24a in this manner. The organic thin film solar cell module in which a plurality of organic photovoltaic cells are connected with each other is thus manufactured.

The first charge transport layer 32, the active layer 40, the second charge transport layer 34 and the second electrode 24 are formed by a method for forming the films in which the coating liquid, that is a solution is used, and the applied and formed layers may be dried in preferable conditions for the material and the solvent under any preferable atmosphere such as a nitrogen gas atmosphere.

As methods for forming the film, coating methods including a spin coating method, a casting method, a microgravure coating method, a gravure coating method, a bar coating method, a roll coating method, a wire-bar coating method, a dip coating method, a spray coating method, a screen printing method, a gravure printing method, a flexographic printing method, an offset printing method, an ink-jet printing method, a dispenser printing method, a nozzle coating method, and a capillary coating method may be used. Preferable methods includes the spin coating method, the flexographic printing method, the gravure printing method, the ink-jet printing method, and the dispenser printing method.

Solvent used for these methods for forming the film that use the solution is not particularly limited as long as the solvent dissolves materials of each layer, is repelled by the lyophobic pattern and is not wetly spread on the lyophobic pattern.

Examples of such solvents may include unsaturated hydrocarbon solvents such as toluene, xylene, mesitylene, tetralin, decalin, bicyclohexyl, n-butylbenzene, sec-butylbenzene, and tert-butylbenzene; halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, and bromocyclohexane; halogenated unsaturated hydrocarbon solvents such as chlorobenzene, dichlorobenzene, and trichlorobenzene; and ether based solvents such as tetrahydrofuran and tetrahydropyran.

Subsequently, a third groove Z exposing a part of the first electrode 22 that is provided in the part between the cells 100B is formed by passing from the surface of the second electrode 24 through the second electrode 24, the second charge transport layer 34, and the active layer 40, and the first charge transport layer 32 (third cutting step).

The third groove Z is a constituent for electrically isolating a first cell 100A1 and a second cell 100A2 by a part between cells 100B. By forming the third groove Z, a plurality of organic photovoltaic cells are formed by isolation. The part between cells 100B is a linear groove shape. In this example, the part between cells 100B separates adjacent cells along a circumference shape (a linear shape in the embodiment) close to a circumferential part of the first electrode 22. The part between cells 100B is preferably a region as small as possible, because the region does not function as a photovoltaic cell. Therefore, the third groove Z is preferably formed in a shape and arranged position in which a size of the part between cells 100B can be as small as possible. For example, the part between cells 100B may be constituted as close as possible to the circumference of the first electrode, and as a linear groove having a width as narrow as possible in the embodiment.

Subsequently, constitution of an apparatus for manufacturing that is preferably applicable for the foregoing cutting steps (at least one cutting step of the first cutting step, the second cutting step, and the third cutting step) in the method for manufacturing the foregoing organic thin film solar cell module, and a cutting step that uses the apparatus for manufacturing are described.

### First Embodiment

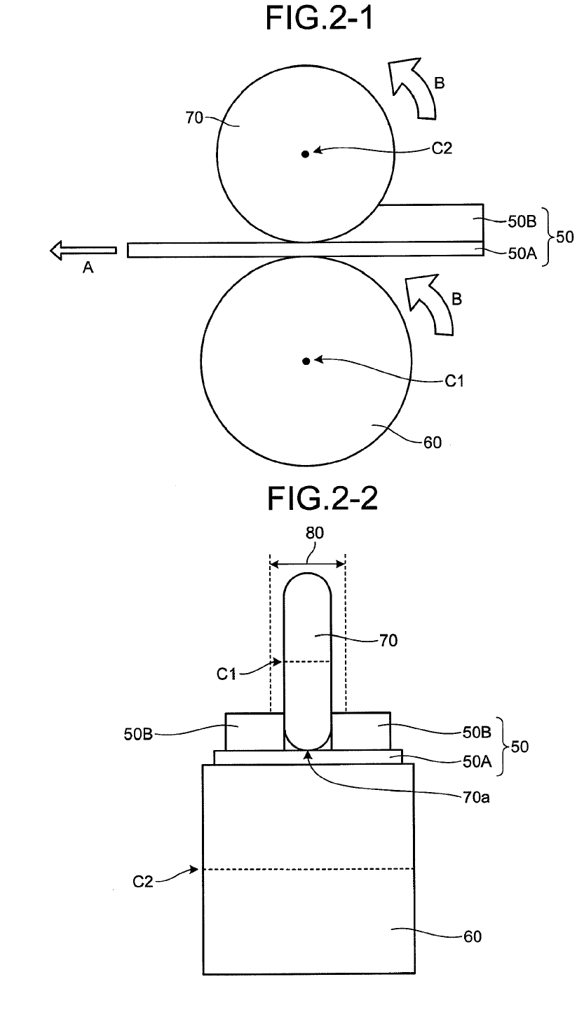

The apparatus for manufacturing and the cutting step according to a first embodiment is described with reference to FIG. 2.

FIG. 2-1 is a schematic side view illustrating the apparatus for manufacturing according to the first embodiment. FIG. 2-2 is a schematic front view illustrating the apparatus for manufacturing according to the first embodiment.

The first embodiment is characterized in that the cutting step is performed by an apparatus for manufacturing comprising a disk-shaped rotary blade.

As shown in FIG. 2-1, the apparatus for manufacturing comprises a carrier roll 60. The carrier roll 60 has a column-shape. The carrier roll 60 is constituted so as to be possible to rotate around a first central rotation axis C1 as a rotation axis in a direction of an outline arrow B, and can carry a layered structure 50 that is in contact with a part of the surface of the carrier roll in a direction of an outline arrow A.

For the carrier roll 60 and the operation mechanism that operates the carrier roll 60, a roll such as any conventionally known preferable carrier roll that is used for manufacturing for an optical film and the like performed in roll-to-roll and an operation mechanism associated therewith can be used.

The apparatus for manufacturing comprises a blade structure 70. The blade structure 70 is a disk-shaped rotary blade in this example. The blade structure 70 has functions in which the blade structure 70 contacts a layer that is a target for cutting (may be referred to as a target layer) with rotating around a second central rotation axis C2 as a rotation axis in a direction of the outline arrow B, thereby cutting the target layer or engraving a groove. The layered structure comprising one or more organic thin films being the target layer may comprise an inorganic layer (a layer not comprising organic compounds) that can be cut (This is similar to other embodiments described below).

In this embodiment, only a second layered body of the layered structure 50 provided on the first layered body 50A being the substrate (on which the first electrode 22 is formed) and comprising the second layered body 50B stacked with one layer or two more layers of the organic thin films are cut. At this time, the carrier roll 60 is in contact with the first layered body 50A and supports the entire layered structure 50.

As shown in FIG. 2-2, specifically, the blade structure 70 is aligned so as to fit its blade width in a scribing region 80 previously set in the layered structure and is rotated around the second central rotation axis C2 as a rotation axis. By this rotation a push cutting process is performed in such a degree that a tip 70a of the blade structure 70 passes through the target layer, that is, the second layered body 50B and the surface of the first layered body 50A is exposed without damage.

When this push cutting process is performed, the layered structure 50 is moved in a direction of the arrow A by the carrier roll 60 as described above with reference to FIG. 2-1. Therefore, in the scribing region 80 of the layered structure 50, a linear groove is engraved by the carrier roll 60 that supports and carries the layered structure 50 and the blade structure body 70. As a result, the surface of the first layered body 50A is exposed and the second layered body 50B is cut by the formed groove.

The blade structure 70 can be constituted by any conventionally known preferable materials having high hardness such as metals such as iron, alloys such as molybdenum steel and stainless steel, a ceramic, and a resin.

The carrier roll 60 can be constituted by any conventionally known preferable materials such as stainless steel. The carrier roll 60 is preferably constituted by a harder material than the material of the blade structure 70.

The blade structure 70 is preferably constituted by defining a shape of the circumferential edge part of the tip 70a, more specifically, a shape of the circumferential edge part in a direction perpendicular to an extended direction of the formed linear groove by a smooth curved line having a curvature radius of 5 μm to 1000 μm.

Generally, the organic thin film is soft. Consequently, the organic thin film can be cut by the push cutting process using the blade having the tip 70a that is not a sharp shape.

For example, in the active layer (the organic thin film) that is a coating film formed on a glass substrate, a groove part can be formed by the push cutting process to which only about 10 mg load is applied when a blade structure body having a curvature radius of 2 μm is used.

Therefore, the apparatus for manufacturing preferably has constitution that comprises a load measurement mechanism to measure a load applied to the organic thin film and a load adjustment mechanism that can control the load in any preferable range when the push cutting process is performed.

In the blade structure 70, a coated film is formed at least in a region comprising the tip 70a that is in contact with the target layer by coating treatment using materials having low friction coefficient such as diamond-structure carbon, amorphous carbon, and polytetrafluoroethylene (PTFE).

By forming such a coated film, friction between the target layer and the blade structure 70 is reduced. As a result, damage of a layer directly below the target layer caused by friction, temperature rising of the target layer, and function loss caused by this temperature rising can be suppressed.

The apparatus for manufacturing according to the first embodiment further comprises a mechanism in which the blade structure 70, particularly in a region in contact with the target layer, can be cleaned by wiping with a solvent, associated with the blade structure 70.

The blade structure 70 being a rotary blade according to the first embodiment can be used in a state with heating. However, the cutting step is preferably preformed using the blade structure 70 without heating in consideration of possibility of function loss of the organic thin film caused by high temperature.

Generation of dust can be suppressed because one layer of a soft organic thin film or a layered structure comprising one or more layers of soft organic thin films are cut by the push cutting process using the foregoing rotary blade. Therefore, deterioration of electrical characteristics of the manufactured organic photovoltaic cell (an organic thin film solar cell module) caused by dust and generation of defects such as short circuit caused by the dust can be suppressed. In addition, yield of the products can be increased. Moreover, since the rotary blade is used, linearity of the formed groove is improved in good accuracy.

### Second Embodiment

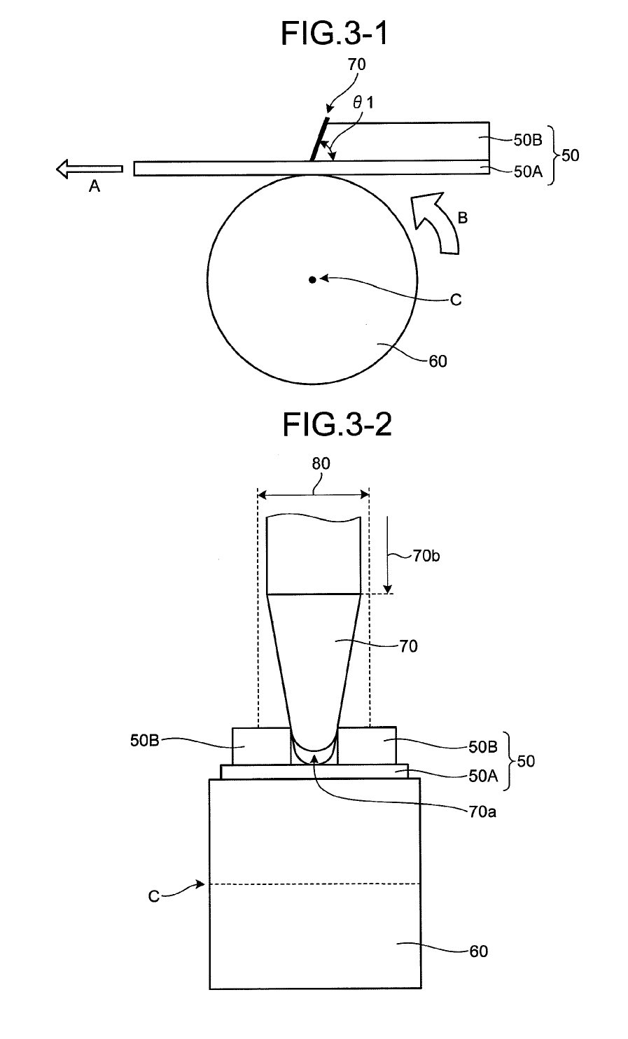

An apparatus for manufacturing and a cutting step according to a second embodiment is described with reference to FIG. 3. Here, constitution elements except a shape of a blade structure in the apparatus for manufacturing are not different from the constitution in the first embodiment that is already described. Therefore, the same references may be assigned and description thereof may be omitted.

FIG. 3-1 is a schematic side view illustrating an apparatus for manufacturing according to the first embodiment. FIG. 3-2 is a schematic front view illustrating the apparatus for manufacturing according to the second embodiment.

The second embodiment is characterized in that the cutting step is performed by an apparatus for manufacturing comprising a stylus-shaped blade.

As shown in FIG. 3-1, the apparatus for manufacturing comprises the carrier roll 60. The carrier roll 60 has a column shape. The carrier roll 60 is constituted so as to be possible to rotate around a central rotation axis C as a rotation axis in a direction of the outline arrow B, and can carry the layered structure 50 that is in contact with a part of the surface of the carrier roll in a direction of the outline arrow A.

The apparatus for manufacturing comprises the blade structure 70. The blade structure 70 is a stylus-shaped pull cutting blade in this example. The blade structure 70 has functions in which the blade structure 70 contacts a layer that is a target for cutting with carrying (moving) the layered structure 50 in a direction of the arrow A by the carrier roll 60 to cut the target layer or to engrave a groove by cutting.

In this embodiment, only the second layered body of the layered structure 50 provided on the first layered body 50A being the substrate (on which the first electrode 22 is formed) and comprising the second layered body 50B stacked with one layer or two more layers of the organic thin films are cut. At this time, the carrier roll 60 is in contact with the first layered body 50A and supports the entire layered structure 50.

As shown in FIG. 3-2, the blade structure 70 has a tapered shape in which a closer part of a tip 70a becomes sharper along heading for the apex. The width of a stylus axis part 70b of the blade structure 70 is preferably 10 μm to 3000 μm.

Specifically, the cutting step is performed by aligning the blade structure 70 so as to fit its blade width in the scribing region 80 previously set in the layered structure 50.

At this time, as shown in FIG. 3-1, an angle θ1 formed by the blade structure 70 (the center) and the surface of the first layered body 50A (the second layered body 50B) is preferably 30° to 60°. By setting θ1 in this range, a load applied to the target layer can become more stable and abrasion of the blade structure 70 can be suppressed.

The step of cutting is performed by fixing a location position of the blade structure 70 in a state of applying a predetermined load with moving the layered structure 50 by rotating the carrier roller 60. By moving the layered structure 50, a pull cutting process is performed in such a degree that the tip 70a of the blade structure 70 passes through the target layer, that is, the second layered body 50B and the surface of the first layered body 50A is exposed without damage.

As a result, in the scribing region 80 of the layered structure 50, a linear groove is engraved by the carrier roll 60 that supports and carries the layered structure 50 and the blade structure 70. As a result, the surface of the first layered body 50A is exposed and the second layered body 50B is cut by the formed groove.

The blade structure 70 can be constituted by any conventionally known preferable materials having high hardness such as metals such as iron, alloys such as stainless steel and carbon tool steels (SKS), ceramics, and resins.

The carrier roll 60 can be constituted by any conventionally known preferable materials such as stainless steel.

The blade structure 70 is preferably constituted by defining a shape of the tip 70a, more specifically, a shape in a direction perpendicular to an extended direction of the formed linear groove (and/or a shape in an extended direction of the groove) by a smooth curved line (partial spherical surface) having a curvature radius of 5 μm to 1000 μm.

The apparatus for manufacturing may have constitution that comprises a load measurement mechanism to measure a load applied to the organic thin film and a load adjustment mechanism that can control the load in any preferable range when the pull cutting process is performed.

In the blade structure 70, a coated film is formed at least in a region comprising the tip 70a that is in contact with the target layer by coating treatment using materials having low friction coefficient such as diamond-structure carbon, amorphous carbon, and polytetrafluoroethylene (PTFE).

By forming such a coated film, friction between the target layer and the blade structure 70 is reduced. As a result, damage of a layer directly below the target layer caused by friction, temperature rising of the target layer, and function loss caused by this temperature rising can be suppressed.

For the stylus-shaped blade structure 70 according to the second embodiment, the step of cutting is preferably preformed using the blade structure 70 without heating, in consideration of possibility of function loss of the organic thin film caused by high temperature.

By the pull cutting process using the foregoing stylus-shaped blade structure 70, one layer of a soft organic thin film and a layered structure comprising one or more layers of soft organic thin films can be cut by forming a groove having a narrower width. Therefore, the organic photovoltaic cell (the organic thin film solar cell module) can be manufactured in further miniaturization and smaller size.

### Third Embodiment

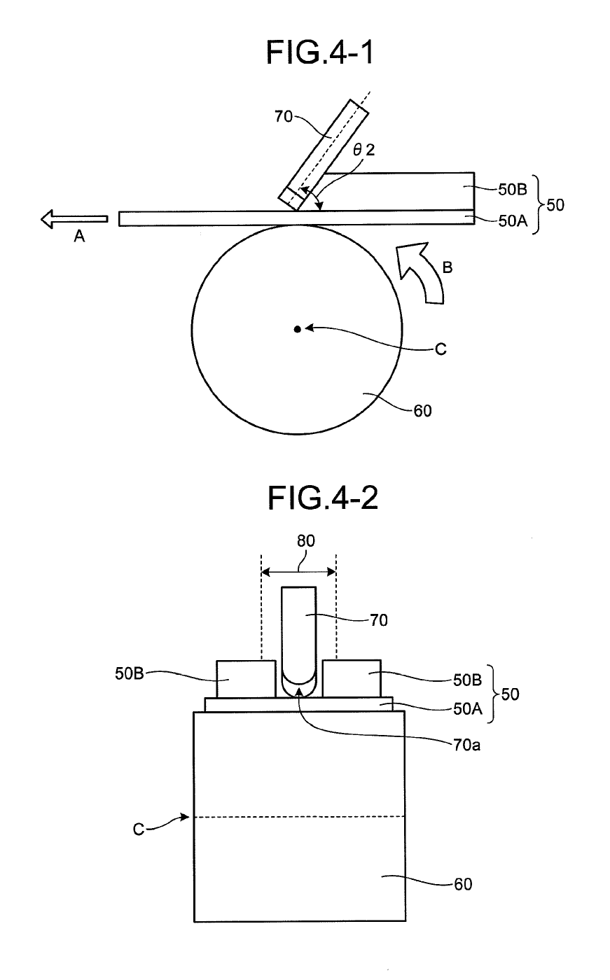

An apparatus for manufacturing and a step of cutting according to a second embodiment is described with reference to FIG. 4. Here, constitution elements except a shape of a blade structure in the apparatus for manufacturing are not different from the constitutions in the first and the second embodiments that are already described. Therefore, the same references may be assigned and description thereof may be omitted.

FIG. 4-1 a schematic side view illustrating an apparatus for manufacturing according to the third embodiment. FIG. 4-2 is a schematic front view illustrating the apparatus for manufacturing according to the third embodiment.

The third embodiment is characterized in that the step of cutting is performed by an apparatus for manufacturing comprising a flat blade-shaped blade structure.

As shown in FIG. 4-1, the apparatus for manufacturing comprises the carrier roll 60. The carrier roll 60 has a column shape. The carrier roll 60 is constituted so as to be possible to rotate around the central rotation axis C as a rotation axis in a direction of the outline arrow B, and can carry the layered structure 50 that is in contact with a part of the surface of the carrier roll in a direction of the outline arrow A.

The apparatus for manufacturing comprises the blade structure 70. The blade structure 70 is a flat blade-shaped pull cutting blade in this example. The blade structure 70 has functions in which the blade structure 70 contacts a layer that is a target for cutting with carrying (moving) the layered structure 50 in a direction of the arrow A by the carrier roll 60 to cut the target layer or to engrave a groove by cutting.

In this embodiment, only the second layered body 50B of the layered structure 50 provided on the first layered body 50A being the substrate (on which the first electrode 22 is formed) and comprising the second layered body 50B stacked with one layer or two more layers of the organic thin films is cut. At this time, the carrier roll 60 is in contact with the first layered body 50A and supports the entire layered structure 50.

As shown in FIG. 4-2, the blade structure 70 is preferably constituted by defining a shape in a direction perpendicular to an extended direction of the groove of the tip 70a (and/or a shape in an extended direction of the groove) by a smooth curved line (partial spherical surface) having a curvature radius of 5 μm to 1000 μm.

The thickness of the flat blade-shaped blade structure 70 is preferably 100 μm to 3000 μm.

Specifically, the cutting step is performed by aligning the blade structure 70 so as to fit its blade width in the scribing region 80 previously set in the layered structure 50.

At this time, as shown in FIG. 4-1, an angle θ2 formed by the blade structure 70 (the center) and the surface of the first layered body 50A (the second layered body 50B) is preferably 30° to 60°. By setting θ2 in this range, a load applied to the target layer can become more stable and abrasion of the blade structure 70 can be suppressed.

The cutting step is performed by fixing a location position of the blade structure 70 in a state of applying a predetermined load with moving the layered structure 50 by rotating the carrier roller 60. By moving the layered structure 50, a pull cutting process is performed in such a degree that the tip 70a of the blade structure 70 passes through the target layer, that is, the second layered body 50B and the surface of the first layered body 50A is exposed without damage.

As a result, in the scribing region 80 of the layered structure 50, a linear groove is engraved by the carrier roll 60 that supports and carries the layered structure 50 and the blade structure 70. As a result, the surface of the first layered body 50A is exposed and the second layered body 50B is cut by the formed groove.

The blade structure 70 can be constituted by any conventionally known preferable materials having high hardness such as high-speed steel, hard metal, a ceramic, and a resin.

The carrier roll 60 can be constituted by any conventionally known preferable materials such as stainless steel.

The apparatus for manufacturing may have constitution that comprises a load measurement mechanism to measure a load applied to the organic thin film and a load adjustment mechanism that can control the load in any preferable range when the pull cutting process is performed.

In the blade structure 70, a coated film is formed at least in a region comprising the tip 70a that is in contact with the target layer by coating treatment using materials having low friction coefficient such as diamond-structure carbon, amorphous carbon, and polytetrafluoroethylene (PTFE).

By forming such a coated film, friction between the target layer and the blade structure 70 is reduced. As a result, damage of a layer directly below the target layer caused by friction, temperature rising of the target layer, and function loss caused by this temperature rising can be suppressed.

For the flat blade-shaped blade structure 70 according to the third embodiment, the step of cutting is preferably preformed using the unheated blade structure 70, in consideration of possibility of function loss of the organic thin film caused by high temperature.

By the pull cutting process using the foregoing flat blade-shaped blade structure 70, one layer of a soft organic thin film and a layered structure comprising one or more layers of soft organic thin films can be cut by forming a groove having high linearity in good accuracy. Since the flat blade-shaped blade structure 70 is relatively low price, the manufacturing cost can be reduced.

In the first embodiment, the second embodiment, and the third embodiment, the constitution in which the apparatus for manufacturing according to the present invention comprises the carrier roll (60) is exemplified and described. However, for example, a conveyer or a machine platen for carry can also be used instead of the carrier roll.

### EXAMPLES

### Example 1

After washing a polyethylene naphthalate (may be referred to as PEN) film substrate (a substrate) (Trade name: OTEC, manufactured by Tobi Co., Ltd.) of which an ITO thin film was provided on one main surface with acetone, ultraviolet ozone cleaning treatment was performed for 15 minutes by an ultraviolet ozone irradiation apparatus equipped with a low-pressure mercury vapor lamp (Type: UV-312, manufactured by Technovision, Inc.), thereby preparing an ITO electrode (a first electrode) having a clear surface on the PEN film substrate. Subsequently, a suspension of PEDOT (Trade name Baytron P AI4083, Lot. HCD07O109, manufactured by Starck) was applied on the PEN film substrate on which the ITO electrode was provided by a spin coating method, thereby forming a PEDOT layer (a first charge transport layer). Thereafter, the substrate was dried at 150° C. for 30 minutes in the atmosphere.

The PEN film substrate is fixed on a glass plate, and the PEDOT layer being an organic thin film was cut into two regions by pushing and running a rotary blade (a blade structure) having a curvature radius of about 50 μm made of stainless steel on the PEDOT layer without heating.

Whether electrical conductivity is obtained between two regions of the ITO electrode provided directly beneath each of the two regions of the cut PEDOT layer was tested, and the conductivity was demonstrated. As a result, it was demonstrated that a groove that exposes the ITO electrode can be formed by cutting only the PEDOT layer without cutting the ITO electrode.

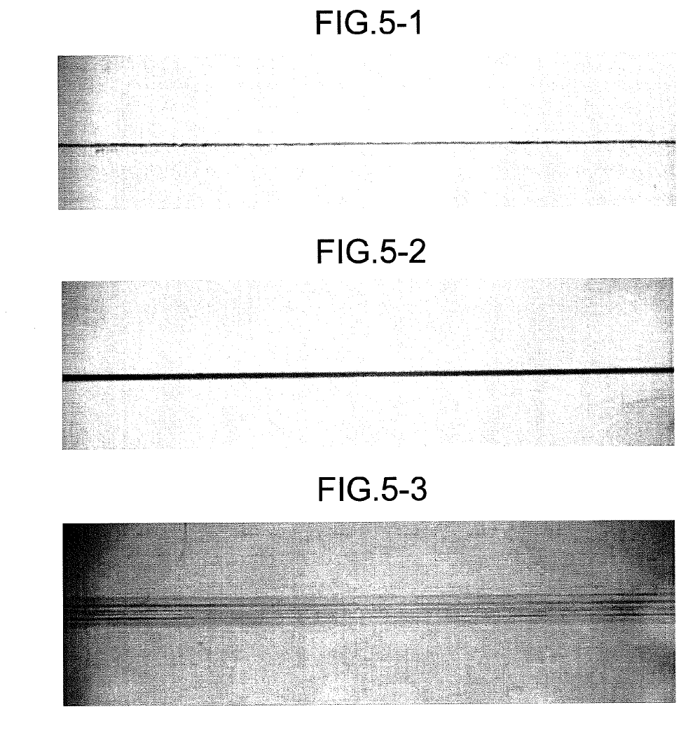

Subsequently, after adding poly (3-hexyl thiophene) (may be referred to as P3HT) (Trade name: lisicon SP001, Lot. EF431002, manufactured by Merck) as the electron donor compound and PCBM (Trade Name: E100, Lot. 7B0168-A, manufactured by Frontier Carbon Corporation) as a fullerene derivative being an electron acceptor compound to an ortho-dichlorobenzene solvent so that P3HT was 1.5% by weight and PCBM was 1.2% by weight and stirring at 70° C. for 2 hours, the mixture was filtered with a filter having a pore diameter of 0.2 μm, thereby preparing a coating liquid. An active layer was formed on the PEDOT layer by applying the coating liquid by a spin coating method. Thereafter, the applied layer was heat treated at 150° C. for 3 minutes in a nitrogen gas atmosphere. A film thickness of the active layer after heat treatment was about 100 nm. As similar to the foregoing case, a layered structure of organic thin films made of the active layer and the PEDOT layer was able to be cut into two regions by pushing and running a rotary blade made of stainless steel to the active layer without heating. An optical microscope image of a cut region (a groove) according to the present invention is shown in FIG. 5-1. The optical microscope image was taken at an optical magnification of 350 times using a light microscope (KH-7700, manufactured by Hirox Co., Ltd.). FIG. 5-2 and FIG. 5-3 described below are taken by the same method.

In the same way as the foregoing case, whether electrical conductivity is obtained between two regions of the ITO electrode provided directly beneath the two regions of the cut layered structure was tested, and the conductivity was demonstrated. As a result, it was demonstrated that a groove that exposes the ITO electrode can be formed by cutting only the layered structure made of the active layer and the PEDOT layer without cutting the ITO electrode.

### Example 2

A step of cutting the single layer or the layered structure was performed similar to Example 1 described above except that a stylus-shaped structure having a curvature radius of about 100 μm made of stainless steel was used as a blade structure.

As a result, it was demonstrated that a groove that exposes the ITO electrode can be formed by cutting only the PEDOT layer on the ITO electrode and only the layered structure made of the active layer and the PEDOT layer without cutting the ITO electrode can be formed. An optical microscope image of a cut region according to the present invention is shown in FIG. 5-2.

### Example 3

A step of cutting the single layer or the layered structure was performed similar to Example 1 described above except that a flat blade-shaped blade structure having a curvature radius of about 1000 μm made of PTFE was used as a blade structure.

As a result, it was demonstrated that a groove that exposes the ITO electrode can be formed by cutting only the PEDOT layer on the ITO electrode and only the layered structure made of the active layer and the PEDOT layer without cutting the ITO electrode can be formed. An optical microscope image of a cut region according to the present invention is shown in FIG. 5-3.

### INDUSTRIAL APPLICABILITY

The present invention is useful for manufacturing the organic thin film solar cell module.

1. A method for manufacturing an organic thin film solar cell module in which a plurality of organic photovoltaic cells are arranged on a substrate, each of which comprises a layered structure comprising a pair of electrodes of a first electrode and a second electrode and one layer of an organic thin film or one or more layers of organic thin films placed between the pair of electrodes, the method comprising the steps of:
cutting the layered structure including one layer of the organic thin film or one or more layers of the organic thin films using a blade structure without heating, thereby forming a groove that passes through the layered structure including one layer of the organic thin film or one or more layers of the organic thin films to exposes a surface of a layer provided directly beneath the layered structure.

2. A method for manufacturing an organic thin film solar cell module, the method comprising the steps of:
forming a plurality of first electrodes on a main surface of a substrate;
forming a first charge transport layer on the first electrode formed on the substrate;
first cutting to form a first groove in a region between the first electrodes for exposing the main surface of the substrate by passing through the first charge transport layer;
forming an active layer covering over the first charge transport layer, and a second charge transport layer covering over the active layer;
second cutting to form a second groove for exposing a part of the first electrode by passing through the first charge transport layer, the active layer, and the second charge transport layer;
forming a second electrode covering over the second charge transport layer and embedded in the second groove; and
third cutting to form a third groove for exposing a part of the first electrode by passing through the second electrode, the second charge transport layer, the active layer, and the first charge transport layer, thereby isolating a plurality of organic photovoltaic cells,
wherein at least one of the first cutting, the second cutting, and the third cutting comprises cutting using a blade structure without heating.

3. The method for manufacturing an organic thin film solar cell module according to claim 1, wherein the step of cutting comprises cutting by a push cutting process using a disk-shaped blade structure.

4. The method for manufacturing an organic thin film solar cell module according to claim 1, wherein the step of cutting comprises cutting by a pull cutting process using a stylus-shaped blade structure.

5. The method for manufacturing an organic thin film solar cell module according to claim 1, wherein the step of cutting comprises cutting by a pull cutting process using a flat blade-shaped blade structure.

6. The method for manufacturing an organic thin film solar cell module according to claim 4, wherein the step of cutting comprises cutting by setting an angle formed by the blade structure and the organic thin film being a cutting target at 30° to 60°.

7. The method for manufacturing an organic thin film solar cell module according to claim 1, wherein a material of the blade structure is selected from the group consisting of a metal, an alloy, a ceramic, and a resin.

8. The method for manufacturing an organic thin film solar cell module according to claim 1, wherein the radius of curvature at a tip of the blade structure is 5 μm to 1000 μm.

9. An organic thin film solar cell module produced by the method for manufacturing according to claim 1.

10. An apparatus for manufacturing an organic thin film solar cell module, the apparatus comprising:
a carrier roll that supports and carries a substrate on which an organic thin film is provided; and
a blade structure that cuts the organic thin film on the substrate supported by the carrier roll in contact with the organic thin film in a state without heating.

11. The apparatus for manufacturing an organic thin film solar cell module according to claim 10, wherein the blade structure has a disk shape capable of performing a push cutting process.

12. The apparatus for manufacturing an organic thin film solar cell module according to claim 10, wherein the blade structure has a stylus shape.

13. The apparatus for manufacturing an organic thin film solar cell module according to claim 10, wherein the blade structure has a flat blade shape.
